(19) United States
(12) Patent Application Publication
(10) Pub. No.: US 2026/0344135 A1
(43) Pub. Date: Oct. 29, 2026

(54) ELECTRONIC DEVICE AND MANUFACTURING METHOD THEREOF

(71) Applicant: INNOLUX CORPORATION, Miao-Li County (TW)

(72) Inventors: Kai CHENG, Miao-Li County (TW); Ming-Chang LIN, Miao-Li County (TW); Fang-Ying LIN, Miao-Li County (TW); Pei-Ying HSIEH, Miao-Li County (TW); Kuan-Jen HUANG, Miao-Li County (TW)

(21) Appl. No.: 19/629,519

(22) Filed: Mar. 26, 2026

(30) Foreign Application Priority Data
Apr. 23, 2025 (CN) 202510514140.9

(51) Int. Cl. H10H 20/857; H10H 20/01; H10H 20/831; H10H 20/85; H10H 29/03

(52) U.S. Cl. CPC H10H 20/857; H10H 20/0364; H10H 20/831; H10H 20/8502; H10H 29/03

(57) ABSTRACT

A manufacturing method of an electronic device including steps of: providing a substrate, wherein the substrate includes a bonding element, and the bonding element includes a first region and a second region separated from each other; providing an electronic unit, wherein the electronic unit includes an electronic element and an electrode electrically connected to the electronic element; transferring the electronic unit onto the substrate, wherein the electrode is stacked on the first region; and applying an energy beam to the second region so that the energy of the energy beam is transmitted from the second region to the first region by heat conduction, so as to bond the electrode to the first region. An electronic device made by the manufacturing method is also provided.

### CROSS REFERENCE TO RELATED APPLICATIONS

This Non-provisional application claims priority under 35 U.S.C. § 119(a) on Patent Application No(s). 202510514140.9 filed in China on Apr. 23, 2025, the entire contents of which are hereby incorporated by reference.

### BACKGROUND

### Technology Field

This disclosure relates to an electronic device and a manufacturing method thereof based on laser bonding technology.

### Description of Related Art

In the conventional manufacturing process of electronic devices, when mass-transferring electronic components (e.g. micro LEDs), the laser system is typically used to provide heat energy so that the electronic components can be welded (bonded) onto the substrate. However, in order to provide sufficient heat energy, the laser beam must provide energy rapidly in a short period of time, which may lead to overheating that exceeds the thermal tolerance of the electronic components. This overheating may affect the structure and/or performance of the electronic components.

### SUMMARY

This disclosure provides an electronic device and a manufacturing method thereof that can moderate the heating rate and provide a more gradual heating profile at the bonding point during laser bonding, thereby avoiding overheating and damage to the electronic elements.

A manufacturing method of an electronic device of this disclosure includes steps of: providing a substrate, wherein the substrate includes a bonding element, and the bonding element includes a first region and a second region separated from each other; providing an electronic unit, wherein the electronic unit includes an electronic element and an electrode electrically connected to the electronic element; transferring the electronic unit onto the substrate, wherein the electrode is stacked on the first region; and applying an energy beam to the second region, wherein an energy of the energy beam is transmitted from the second region to the first region by heat conduction so as to bond the electrode to the first region.

Another manufacturing method of an electronic device of this disclosure includes steps of: providing a substrate, wherein the substrate includes a first bonding element and a second bonding element, the first bonding element includes a first bonding region and a third region, and the second bonding element includes a second bonding region and a fourth region; providing an electronic unit, wherein the electronic unit includes an electronic element, and the electronic unit further includes a first electrode and a second electrode electrically connected to the electronic element; transferring the electronic unit onto the substrate, wherein the first electrode is stacked on the first bonding region, and the second electrode is stacked on the second bonding region; and applying an energy beam to the first bonding region and the second bonding region, wherein the first electrode is bonded to the first bonding region, and the second electrode is bonded to the second bonding region. An area of the first electrode is smaller than an area of the second electrode, and an area of the third region is larger than an area of the fourth region.

An electronic device of this disclosure includes a substrate and an electronic unit. The substrate includes a first bonding element and a second bonding element. The first bonding element includes a first bonding region and a third region, and the second bonding element includes a second bonding region and a fourth region. The electronic unit includes an electronic element, a first electrode and a second electrode. The first electrode and a second electrode are electrically connected to the electronic element. The first electrode is stacked on the first bonding region, and the second electrode is stacked on the second bonding region. The area of the first electrode is smaller than the area of the second electrode, and the area of the third region is larger than the area of the fourth region.

### BRIEF DESCRIPTION OF THE DRAWINGS

The disclosure will become more fully understood from the detailed description and accompanying drawings, which are given for illustration only, and thus are not limitative of the present disclosure, and wherein:

FIGS. 1A and 1B are schematic flow charts of a manufacturing method of an electronic device according to an embodiment of this disclosure;

FIGS. 2A and 2B are a top view and a sectional view of a part of the electronic device during the manufacturing process according to the manufacturing method of FIG. 1B;

FIGS. 3A and 3B are a top view and a sectional view of a part of another electronic device during the manufacturing process according to the manufacturing method of FIG. 1B;

FIGS. 4A and 4B are a top view and a sectional view of a part of another electronic device during the manufacturing process according to the manufacturing method of FIG. 1B;

FIGS. 5A and 5B are schematic flow charts of a manufacturing method of an electronic device according to another embodiment of this disclosure;

FIGS. 6A and 6B are a top view and a sectional view of a part of the electronic device during the manufacturing process according to the manufacturing method of FIG. 5B;

FIGS. 7A and 7B are a top view and a sectional view of a part of another electronic device during the manufacturing process according to the manufacturing method of FIG. 5B; and

FIGS. 8A and 8B are a top view and a sectional view of a part of another electronic device during the manufacturing process according to the manufacturing method of FIG. 5B.

### DETAILED DESCRIPTION OF THE DISCLOSURE

The present disclosure will be apparent from the following detailed description, which proceeds with reference to the accompanying drawings, wherein the same references relate to the same elements.

To be noted, the features of several different embodiments may be replaced, reorganized, or combined to create other embodiments without departing from the spirit of the present disclosure.

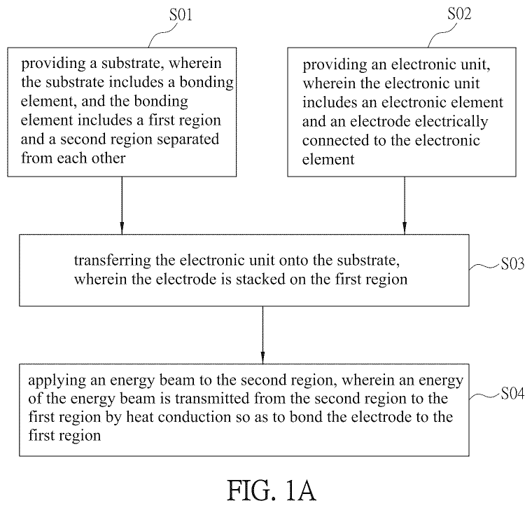

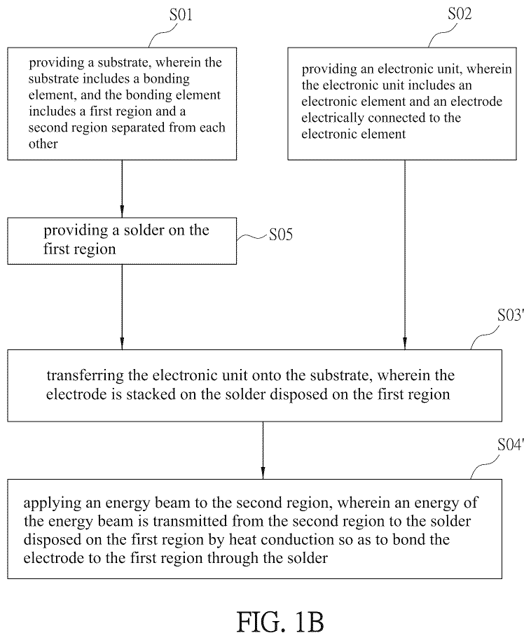

Referring to FIG. 1A, a manufacturing method of an electronic device of this embodiment includes the following steps of: providing a substrate, wherein the substrate includes a bonding element, and the bonding element includes a first region and a second region separated from each other (step S01); providing an electronic unit, wherein the electronic unit includes an electronic element and an electrode electrically connected to the electronic element (step S02); transferring the electronic unit onto the substrate, wherein the electrode is stacked on the first region (step S03); and applying an energy beam to the second region, wherein an energy of the energy beam is transmitted from the second region to the first region by heat conduction so as to bond the electrode to the first region (step S04). In addition, referring to FIG. 1B, the manufacturing method of an electronic device of this embodiment may include the following steps of: providing a substrate, wherein the substrate includes a bonding element, and the bonding element includes a first region and a second region separated from each other (step S01); providing an electronic unit, wherein the electronic unit includes an electronic element and an electrode electrically connected to the electronic element (step S02); providing a solder on the first region (step S05); transferring the electronic unit onto the substrate, wherein the electrode is stacked on the solder disposed on the first region (step S03′); and applying an energy beam to the second region, wherein an energy of the energy beam is transmitted from the second region to the solder disposed on the first region by heat conduction so as to bond the electrode to the first region through the solder (step S04′).

To be noted, the difference between the methods of FIG. 1A and FIG. 1B is that the method of FIG. 1B further includes the step of providing a solder on the first region for bonding the electrode to the bonding element. Based on the method of FIG. 1A, the electrode is directly disposed on the first region of the bonding element, wherein the first region can be defined as a region of the bonding element overlapping with the electrode. Based on the method of FIG. 1B, the electrode is bonded to the first region through the solder, wherein the first region can be defined as a region or a portion of the bonding element overlapping with the solder. In addition, the second region can be defined as a region or a portion of the bonding element irradiated by the energy beam.

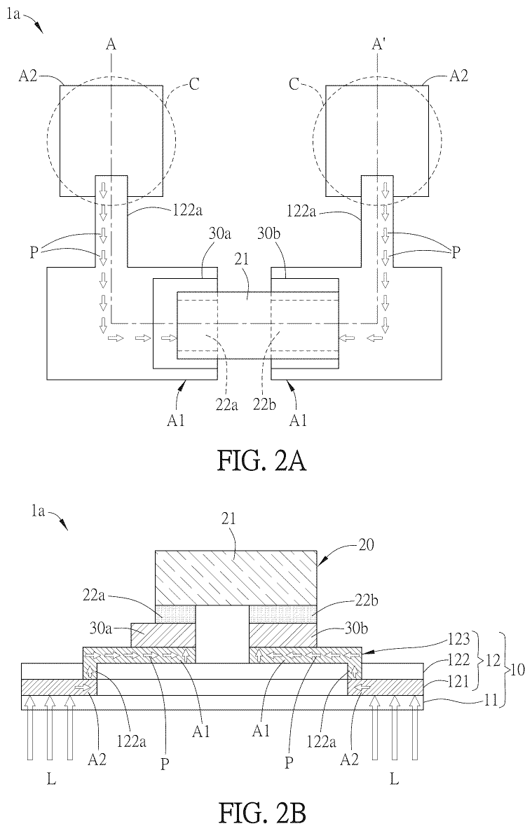

The procedure of the manufacturing method of an electronic device of this embodiment will be described hereinafter with reference to FIGS. 1B, 2A and 2B.

The step S01 is to provide a substrate 10. Referring to FIGS. 2A and 2B, the substrate 10 includes a circuit layer 11 and a bonding element 12, and the bonding element 12 includes a first region A1 and a second region A2, which are separated from each other. Specifically, the circuit layer 11 can be formed on a base (not shown), which can be, for example but not limited to, a flexible or rigid base. The circuit layer 11 may include various passive and/or active components, such as, for example but not limited to, resistors, capacitors, inductors, diodes, MOSFETs, CMOS transistors, BJTs, LDMOS transistors, high-power MOSFETs, TFTs, or other types of transistors. Additionally, the bonding element 12 may include a multilayer structure. As shown in FIG. 2B, the bonding element 12 may include a first metal layer 121, an insulating layer 122, and a second metal layer 123. The first metal layer 121 is disposed on the circuit layer 11, the insulating layer 122 is disposed on the first metal layer 121, and the second metal layer 123 is disposed on the insulating layer 122.

The first metal layer 121 has a plurality of conductive regions formed, for example, by a metallic material, which can respectively constitute the aforementioned second region A2. An insulating material can be disposed between the plurality of conductive regions, so that the plurality of conductive regions are electrically insulated from each other. The material of the second region A2 may include a material with high energy absorption. In this embodiment, the material with high energy absorption is, for example, a material that can absorb the energy of an infrared beam, such as, for example but not limited to, one or more of nickel, cobalt, chromium, and tungsten.

The insulating layer 122 is mainly formed of insulating material and has a plurality of through holes 122a. The through holes 122a penetrates through the insulating layer 122 and connect the upper surface and the lower surface of the insulating layer 122. These through holes 122a can be provided, for example, corresponding to the second regions A2. Specifically, each through hole 122a is connected to one second region A2. In this embodiment, the through holes 122a can be provided with a material with a high thermal conductivity, such as, for example but not limited to, one or more of silver, copper, gold, and aluminum.

The second metal layer 123 has a plurality of conductive regions formed, for example, by a metallic material, which can respectively constitute the aforementioned first region A1. The intervals between the plurality of conductive regions can be disposed with an insulating material or be filled with no material, so that the plurality of conductive regions are electrically insulated from each other. The material of the first region A1 can include materials with high thermal conductivity, such as, for example but not limited to, one or more of silver, copper, gold, and aluminum. Since the first region A1 is formed on the second metal layer 123 and the second region A2 is formed on the first metal layer 121, the first region A1 and the second region A2 can be separated from each other. In this embodiment, the first region A1 and the second region A2 are disposed on different metal layers (as shown in FIG. 2B), and they do not overlap in the top view direction (as shown in FIG. 2A).

Next, the step S02 is to provide an electronic unit 20, which includes an electronic element 21 and at least one electrode electrically connected to the electronic element 21. In this embodiment, the electronic unit 20 includes a first electrode 22a and a second electrode 22b. Specifically, the electronic unit 20 can be, for example, a light-emitting unit, the electronic element 21 can be, for example, a micro LED, and the first electrode 22a and the second electrode 22b are the two electrodes of the micro LED. In practice, multiple electronic units 20 can be provided using mass transfer. First, a large number of electronic units 20 can be placed on a temporary carrier (not shown), and then the electronic units 20 are picked up from the temporary carrier using a transfer device. The picked electronic units 20 can be transferred to the target substrate (e.g. the substrate 10) later. In addition, the multiple electrodes of the electronic unit 20 can have different sizes. As shown in FIGS. 2A and 2B, in this embodiment, the size (area) of the first electrode 22a is smaller than the size (area) of the second electrode 22b.

Afterwards, the step S05 is to provide a solder on the first region A1. In this embodiment, as shown in FIGS. 2A and 2B, multiple solders, such as the solders 30a and 30b, can be provided on multiple first regions A1 by using chemical plating, vapor deposition process, and/or solder dispenser process.

After the steps S02 and S05, the step S03′ is to transfer the electronic unit 20 picked up from the temporary carrier to the substrate 10, and the electrodes (e.g. the first electrode 22a and the second electrode 22b) are respectively stacked on the solders 30a and 30b disposed on the first region A1.

Finally, the step S04′ is to apply an energy beam L to the second region A2 to transfer the energy of the energy beam L through heat conduction from the second region A2 to the solder 30a and 30b disposed on the first region A1, so that the electrodes (e.g. the first electrode 22a and the second electrode 22b) are respectively bonded to the first regions A1 through the solder 30a and 30b, thereby obtaining the electronic device 1a. In this embodiment, the energy beam L can be applied from the side of the substrate 10 away from the electronic unit 20 (see FIG. 2B), and the energy beam L can form multiple light spots C on the second regions A2 (see FIG. 2A). The energy beam L is, for example, an infrared beam. The second regions A2 can absorb the energy of the energy beam L and generate heat. The generated heat can be transferred from the second region A2 (the first metal layer 121) through the through hole 122a (the insulating layer 122) to the corresponding first region A1 (the second metal layer 123) by heat conduction, and then to the solders 30a and 30b disposed on the first regions A1. The heat transfer paths are shown by arrows P in FIGS. 2A and 2B. After the solders 30a and 30b are heated, they can respectively bond the first electrode 22a and the second electrode 22b to the corresponding first regions A1.

In this embodiment, the energy beam L is directly irradiated at the places far away from the bonding points (i.e., the second regions A2), and then the heat energy is indirectly transferred to the solders 30a and 30b, so that the heating rate at the bonding points (i.e., where the solders 30a and 30b are disposed) can be moderated and gently increased with a more gradual heating profile, thereby avoiding overheating and damage to the electronic element 21. Furthermore, in the completed electronic device 1a, the first electrode 22a can be electrically connected to the circuit layer 11 through the solder 30a, the second metal layer 123, the through hole 122a, and the first metal layer 121, while the second electrode 22b can be electrically connected to the circuit layer 11 through the solder 30b, the second metal layer 123, the through hole 122a, and the first metal layer 121. Therefore, the driving current and the control signals can be input to the electronic unit 20 via the circuit layer 11 to drive the electronic unit 20 to operate.

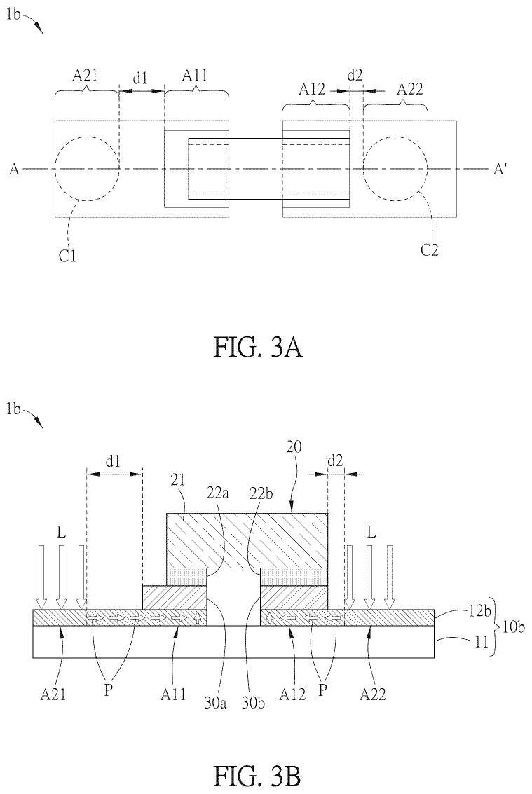

In the above embodiment, the first region A1 and the second region A2 are respectively disposed on different metal layers of the bonding element 12, such as the second metal layer 123 and the first metal layer 121. In other embodiments, the first region A1 and the second region A2 may be disposed on the same metal layer of the bonding element 12, as will be described below with reference to FIGS. 3A and 3B.

Referring to FIGS. 3A and 3B, the step S01 provides a substrate 10b, which includes a circuit layer 11 and a bonding element 12b. The bonding element 12b is disposed on the circuit layer 11 and may be formed, for example, by a single metal layer. This single metal layer has a plurality of conductive regions formed, for example, by a metallic material. For example, one of the conductive regions includes a first region A11 and a second region A21 that are separated from each other, and another one of the conductive regions includes a first region A12 and a second region A22 that are separated from each other. In addition, the single metal layer constituting the bonding element 12b may be formed by one or more materials. For example, in this embodiment, the bonding element 12b (including the first region A11, the second region A21, the first region A12 and the second region A22) may include a material with high energy absorption, such as, for example but not limited to, one or more of nickel, cobalt, chromium, and tungsten. In this embodiment, the first region A11 and the second region A21 are disposed on the same metal layer, and the first region A12 and the second region A22 are disposed on the same metal layer (as shown in FIG. 3B). Furthermore, in the top view direction, the first region A11 and the second region A21 do not overlap, and the first region A12 and the second region A22 do not overlap (as shown in FIG. 3A).

Accordingly, in the step S04′, the energy beam L can be applied from the side of the substrate 10 adjacent to the electronic unit 20 (as shown in FIG. 3B), and the energy beam L can form multiple light spots C1 and C2 on the second regions A21 and A22 (as shown in FIG. 3A). The second regions A21 and A22 can absorb the energy of the energy beam L and generate heat. The generated heat can be transferred from the second region A21 to the first region A11 by heat conduction, and then to the solder 30a disposed on the first region A11. In addition, the generated heat can also be transferred from the second region A22 to the first region A12 by heat conduction, and then to the solder 30b disposed on the first region A12. The heat transfer paths are shown by the arrows P as shown in FIG. 3B. After the solders 30a and 30b are heated, they can respectively bond the first electrode 22a and the second electrode 22b to the corresponding first regions A11 and A12. In this embodiment, the energy beam L is directly irradiated at the place far from the bonding points (i.e., the second regions A21 and A22), and then the heat energy is indirectly transferred to the solders 30a and 30b, so that the heating rate at the bonding points (i.e., where the solders 30a and 30b are disposed) can be moderated and gently increased with a more gradual heating profile, thereby avoiding overheating and damage to the electronic element 21. Furthermore, in the completed electronic device 1b, the first electrode 22a can be electrically connected to the circuit layer 11 through the solder 30a and the bonding element 12b, while the second electrode 22b can be electrically connected to the circuit layer 11 through the solder 30b and the bonding element 12b. Therefore, the driving current and the control signals can be input to the electronic unit 20 via the circuit layer 11 to drive the electronic unit 20 to operate.

To be noted, since the area of the first electrode 22a is smaller than the area of the second electrode 22b, the distance d1 between the second region A21 and the first region A11 can be designed to be greater than the distance d2 between the second region A22 and the first region A12. Therefore, the heating rate of the first region A11, which is connected to the first electrode 22a with smaller area, can be lower than the heating rate of the first region A12, which is connected to the second electrode 22b with larger area. This design can effectively heat the solder 30a and 30b by heat conduction, while avoiding overheating and damage to the electronic element 21.

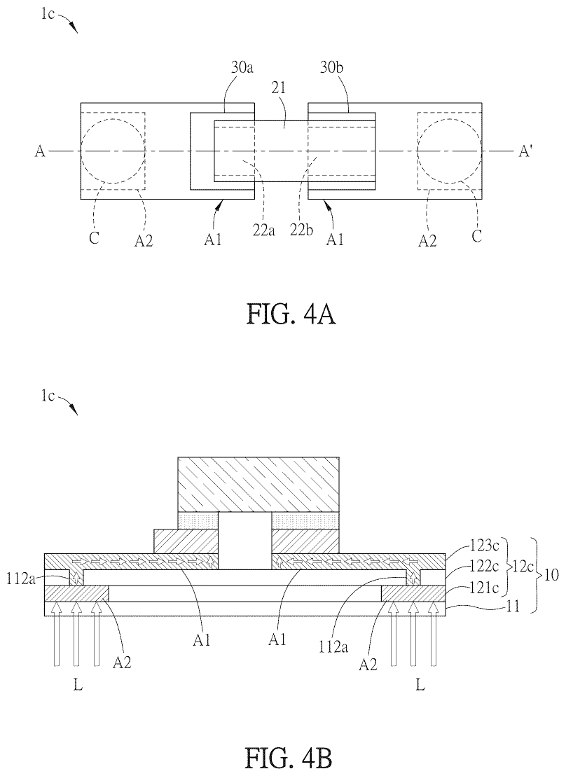

Referring to FIGS. 4A and 4B, in the electronic device 1c, the second region A2 is positioned below the first region A1. Specifically, as shown in FIG. 4B, the bonding element 12c may include a first metal layer 121c, an insulating layer 122c, and a second metal layer 123c. The first metal layer 121c is disposed on the circuit layer 11, the insulating layer 122c is disposed on the first metal layer 121c, and the second metal layer 123c is disposed on the insulating layer 122c. The second region A2 of the first metal layer 121c overlaps with the through hole 122a of the insulating layer 122c, and is disposed below the second metal layer 123c. In this embodiment, the first region A1 and the second region A2 are disposed on different metal layers (as shown in FIG. 4B), and in the top view direction, the first region A1 and the second region A2 at least partially overlap with each other (as shown in FIG. 4A).

To be noted, in the above embodiments, the applied energy beam L directly irradiates the second regions A2, A21, and A22. Therefore, during reverse engineering of the electronic device, the traces formed by the direct irradiation of the energy beam L on the second regions A2, A21, and A22 can be clearly observed, such as burn marks, scorch marks, colored patterns, local terrain changes, or the likes.

In addition, this disclosure also provides electronic devices manufactured by the above mentioned methods as shown in FIGS. 1A and 1B.

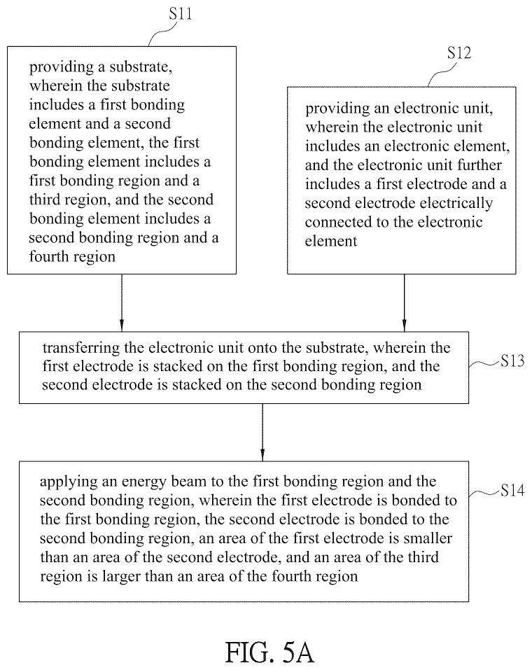

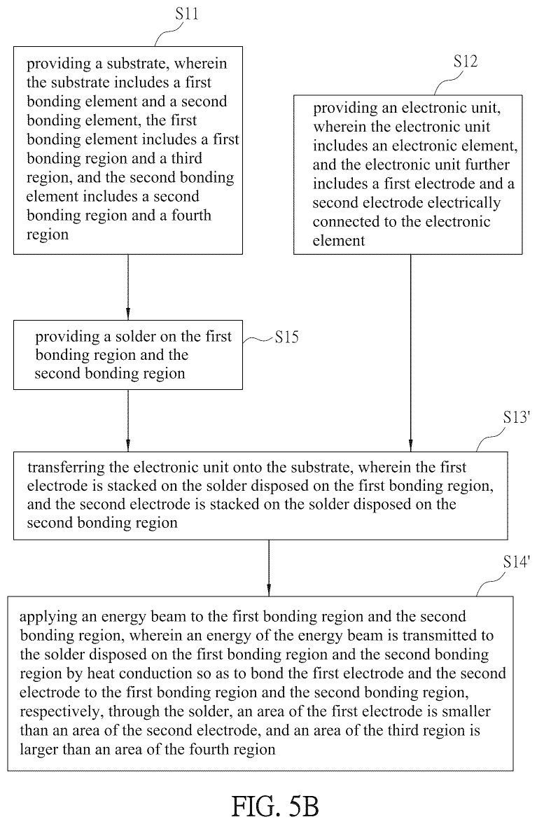

As shown in FIG. 5A, a manufacturing method of an electronic device according to another embodiment of this disclosure includes the following steps of: providing a substrate, wherein the substrate includes a first bonding element and a second bonding element, the first bonding element includes a first bonding region and a third region, and the second bonding element includes a second bonding region and a fourth region (step S11); providing an electronic unit, wherein the electronic unit includes an electronic element, and the electronic unit further includes a first electrode and a second electrode electrically connected to the electronic element (step S12); transferring the electronic unit onto the substrate, wherein the first electrode is stacked on the first bonding region, and the second electrode is stacked on the second bonding region (step S13); and applying an energy beam to the first bonding region and the second bonding region, wherein the first electrode is bonded to the first bonding region, the second electrode is bonded to the second bonding region, an area of the first electrode is smaller than an area of the second electrode, and an area of the third region is larger than an area of the fourth region (step S14). In addition, as shown in FIG. 5B, the manufacturing method of an electronic device according to another embodiment of this disclosure may include the following steps of: providing a substrate, wherein the substrate includes a first bonding element and a second bonding element, the first bonding element includes a first bonding region and a third region, and the second bonding element includes a second bonding region and a fourth region (step S11); providing an electronic unit, wherein the electronic unit includes an electronic element, and the electronic unit further includes a first electrode and a second electrode electrically connected to the electronic element (step S12); providing a solder on the first bonding region and the second bonding region (step S15); transferring the electronic unit onto the substrate, wherein the first electrode is stacked on the solder disposed on the first bonding region, and the second electrode is stacked on the solder disposed on the second bonding region (step S13′); and applying an energy beam to the first bonding region and the second bonding region, wherein an energy of the energy beam is transmitted to the solder disposed on the first bonding region and the second bonding region by heat conduction so as to bond the first electrode and the second electrode to the first bonding region and the second bonding region, respectively, through the solder, an area of the first electrode is smaller than an area of the second electrode, and an area of the third region is larger than an area of the fourth region (step S14′).

The method as shown in FIG. 5B further provides the solder on the first bonding region and the second bonding region to bond the first electrode and the second electrode to the first bonding region and the second bonding region, respectively. In the method as shown in FIG. 5A, the first electrode and the second electrode are directly bonded to the first bonding region and the second bonding region, respectively, wherein the first bonding region can be defined as the region of the first bonding element overlapping with the first electrode, and the second bonding region can be defined as the region of the second bonding element overlapping with the second electrode. In the method as shown in FIG. 5B, the first electrode and the second electrode are bonded to the first bonding region and the second bonding region, respectively, through solder, wherein the first bonding region can be defined as the region the first bonding element overlapping with the solder, and the second bonding region can be defined as the region of the second bonding element overlapping with the solder. In addition, the third region can be defined as the residual region of the first bonding element other than the first bonding region, and the fourth region can be defined as the residual region of the second bonding element other than the second bonding region.

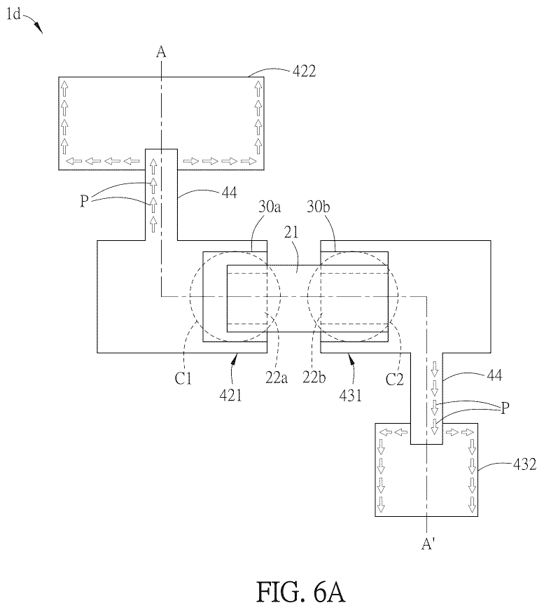

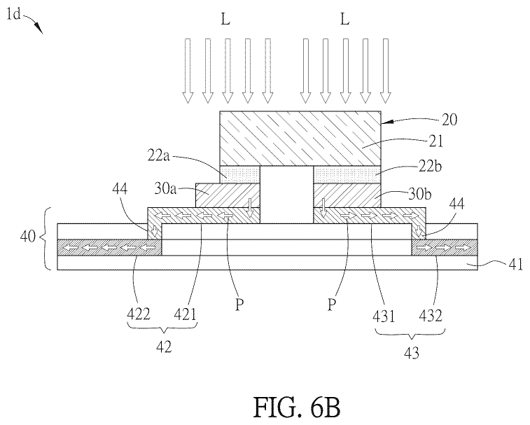

The procedure of the manufacturing method of an electronic device of this embodiment will be described hereinafter with reference to FIGS. 5B, 6A and 6B.

The step S11 is to provide a substrate 40. Referring to FIGS. 6A and 6B, the substrate 40 includes a circuit layer 41 and a plurality of bonding elements disposed on the circuit layer 41. For example, the bonding elements includes a first bonding element 42 and a second bonding element 43. The first bonding element 42 includes a first bonding region 421 and a third region 422, and the second bonding element 43 includes a second bonding region 431 and a fourth region 432. As shown in FIGS. 6A and 6B, the area of the third region 422 is larger than the area of the fourth region 432. Specifically, the circuit layer 41 can be formed on a base (not shown), which can be, for example but not limited to, a flexible or rigid base. The circuit layer 41 may include various passive and/or active components, such as, for example but not limited to, resistors, capacitors, inductors, diodes, MOSFETs, CMOS transistors, BJTs, LDMOS transistors, high-power MOSFETs, TFTs, or other types of transistors. Additionally, the bonding element may include a multilayer structure. As shown in FIG. 6B, the bonding element may include a first metal layer, an insulating layer (including through holes 44), and a second metal layer. The first metal layer, the insulating layer (including through holes 44), and the second metal layer are disposed on the circuit layer 41.

The first metal layer has a plurality of conductive regions formed, for example, by a metallic material, which can respectively constitute the third region 422 and the fourth region 432. An insulating material can be disposed between the plurality of conductive regions, so that the plurality of conductive regions are electrically insulated from each other. The material of the third region 422 and the fourth region 432 may include a material with high thermal conductivity, such as, for example but not limited to, one or more of silver, copper, gold, and aluminum.

The insulating layer is mainly formed of insulating material and has a plurality of through holes 44. The through holes 44 penetrates through the insulating layer and connect the upper surface and the lower surface of the insulating layer. These through holes 44 can be provided, for example, corresponding to the third region 422 and the fourth region 432. In this embodiment, the through holes 44 can be provided with a material with a high thermal conductivity, such as, for example but not limited to, one or more of silver, copper, gold, and aluminum.

The second metal layer has a plurality of conductive regions formed, for example, by a metallic material, which can respectively constitute the first bonding region 421 and the second bonding region 431. The intervals between the plurality of conductive regions can be disposed with an insulating material or be filled with no material, so that the plurality of conductive regions are electrically insulated from each other. The material of the first bonding region 421 and the second bonding region 431 can include a material with high energy absorption. In this embodiment, the material with high energy absorption is, for example, a material that can absorb the energy of an infrared beam, such as, for example but not limited to, one or more of nickel, cobalt, chromium, and tungsten. In this embodiment, the first bonding region 421 and the third region 422 are disposed on different metal layers, and the second bonding region 431 and the fourth region 432 are disposed on different metal layers (as shown in FIG. 6B). As shown in FIG. 6A, in the top view direction, the first bonding region 421 and the third region 422 do not overlap, and the second bonding region 431 and the fourth region 432 also do not overlap.

Next, the step S12 is to provide an electronic unit 20, which includes an electronic element 21 and at least one electrode electrically connected to the electronic element 21. In this embodiment, the electronic unit 20 includes a first electrode 22a and a second electrode 22b. Specifically, the electronic unit 20 can be, for example, a light-emitting unit, the electronic element 21 can be, for example, a micro LED, and the first electrode 22a and the second electrode 22b are the two electrodes of the micro LED. In practice, multiple electronic units 20 can be provided using mass transfer. First, a large number of electronic units 20 can be placed on a temporary carrier (not shown), and then the electronic units 20 are picked up from the temporary carrier using a transfer device. The picked electronic units 20 can be transferred to the target substrate (e.g. the substrate 40) later. In addition, as shown in FIGS. 6A and 6B, in this embodiment, the area of the first electrode 22a is smaller than the area of the second electrode 22b.

Afterwards, the step S15 is to provide a solder on the first bonding region 421 and the second bonding region 431. In this embodiment, as shown in FIGS. 6A and 6B, multiple solders, such as the solders 30a and 30b, can be provided on multiple first bonding regions 421 and second bonding regions 431 by using chemical plating, vapor deposition process, and/or solder dispenser process.

After the steps S12 and S15, the step S13′ is to transfer the electronic unit 20 picked up from the temporary carrier to the substrate 40, and the first electrode 22a and the second electrode 22b are respectively stacked on the solder 30a disposed on the first bonding region 421 and the solder 30b disposed on the second bonding region 431.

Finally, the step S14′ is to apply an energy beam L to the first bonding region 421 and the second bonding region 431 to transfer the energy of the energy beam L through heat conduction from the first bonding region 421 to the solder 30a and from the second bonding region 431 to the solder 30b, so that the first electrode 22a and the second electrode 22b are respectively bonded to the first bonding region 421 and the second bonding region 431 through the solder 30a and 30b, thereby obtaining the electronic device 1d. In this embodiment, the energy beam L can be applied from the side of the substrate 40 away from the electronic unit 20 (see FIG. 6B), and the energy beam L can form multiple light spots C1 and C2 on the first bonding region 421 and the second bonding region 431, respectively (see FIG. 6A). The energy beam L is, for example, an infrared beam. The first bonding region 421 and the second bonding region 431 can absorb the energy of the energy beam L and generate heat. The generated heat can be partially transferred to the solder 30a disposed on the first bonding region 421 and the solder 30b disposed on the second bonding region 431. The heated solders 30a and 30b can bond the first electrode 22a and the second electrode 22b to the first bonding region 421 and the second bonding region 431, respectively. In addition, a part of the generated heat can be respectively transferred from the first bonding region 421 and the second bonding region 431 to the third region 422 and the fourth region 432 by heat conduction to perform heat dissipation. The heat dissipation paths are shown by the arrows P in FIGS. 6A and 6B.

In this embodiment, the third region 422 is separately disposed from the first bonding region 421, and the fourth region 432 is separately disposed from the second bonding region 431. Therefore, the energy of the energy beam L provided to the first bonding region 421 and the second bonding region 431 is partially transferred to the third region 422 and the fourth region 432. This design can moderate the heating rate and provide a more gradual heating profile at the bonding points (i.e., where the solder 30a and 30b are disposed), thereby avoiding overheating and damage to the electronic element 21. In addition, in the completed electronic device 1d, the first electrode 22a can be electrically connected to the circuit layer 41 through the solder 30a, the first bonding region 421, the through hole 44 and the third region 422, and the second electrode 22b can be electrically connected to the circuit layer 41 through the solder 30b, the second bonding region 431, the through hole 44 and the fourth region 432. Therefore, the driving current and the control signals can be input to the electronic unit 20 through the circuit layer 41 to drive the electronic unit 20 to operate.

To be noted, since the area of the first electrode 22a is smaller than the area of the second electrode 22b, the area of the third region 422 can be designed to be larger than the area of the fourth region 432. Therefore, the heat dissipation area provided by the third region 422, which is connected to the first electrode 22a with smaller area, can be greater than the heat dissipation area provided by the fourth region 432, which is connected to the second electrode 22b with larger area. This design can effectively balance the heating rates of the solder 30a and the solder 30b, and avoid overheating and damage to the electronic element 21.

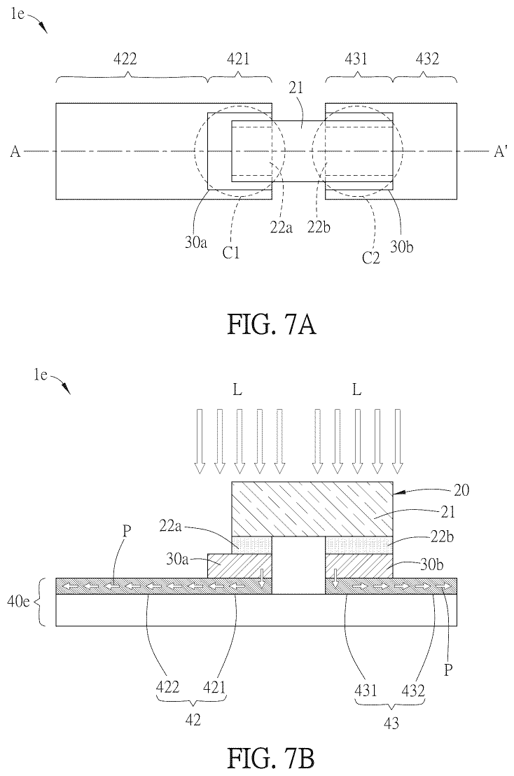

In the above embodiment, the first bonding region 421 and the third region 422 of the first bonding element 42 are respectively disposed on different metal layers, and the second bonding region 431 and the fourth region 432 of the second bonding element 43 are respectively disposed on different metal layers. In other embodiments, the first bonding region 421 and the third region 422 of the first bonding element 42 may be disposed on the same metal layer, and the second bonding region 431 and the fourth region 432 of the second bonding element 43 may be disposed on the same metal layer, as will be described below with reference to FIGS. 7A and 7B.

Referring to FIGS. 7A and 7B, the step S11 is to provide a substrate 40e, which includes a circuit layer 41 and a plurality of bonding elements disposed on the circuit layer 41. For example, the bonding elements includes a first bonding element 42 and a second bonding element 43. The first bonding element 42 includes a first bonding region 421 and a third region 422, and the second bonding element 43 includes a second bonding region 431 and a fourth region 432. The first bonding element 42 and the second bonding element 43 may, for example, be formed by multiple conductive regions of a single metal layer, wherein one conductive region includes the first bonding region 421 and the third region 422 that are separated from each other, and another conductive region includes a second bonding region 431 and a fourth region 432 that are separated from each other. In this case, the area of the first electrode 22a is smaller than the area of the second electrode 22b, and the area of the third region 422 is larger than the area of the fourth region 432. The single metal layer constituting the first bonding element 42 and the second bonding element 43 can be formed of one or more materials. For example, in this embodiment, the first bonding element 42 (including the first bonding region 421 and the third region 422) and the second bonding element 43 (including the second bonding region 431 and the fourth region 432) can include materials with high energy absorption, such as, for example but not limited to, one or more of nickel, cobalt, chromium, and tungsten. In this embodiment, the first bonding region 421 and the third region 422 are disposed on the same metal layer, and the second bonding region 431 and the fourth region 432 are disposed on the same metal layer (as shown in FIG. 7B). as shown in FIG. 7A, in the top view direction, the first bonding region 421 and the third region 422 do not overlap with each other, and the second bonding region 431 and the fourth region 432 do not overlap with each other.

Accordingly, in the step S14′, the energy beam L can be applied from the side of the substrate 40e away from the electronic unit 20 (as shown in FIG. 7B), and the energy beam L can form multiple light spots C1 and C2 on the first bonding region 421 and the second bonding region 431 (as shown in FIG. 7A). The first bonding region 421 and the second bonding region 431 can absorb the energy of the energy beam L and generate heat. The generated heat can be partially transferred to the solder 30a disposed on the first bonding region 421 and the solder 30b disposed on the second bonding region 431. The heated solders 30a and 30b can bond the first electrode 22a and the second electrode 22b to the first bonding region 421 and the second bonding region 431, respectively. In addition, a part of the generated heat can be respectively transferred from the first bonding region 421 and the second bonding region 431 to the third region 422 and the fourth region 432 by heat conduction to perform heat dissipation. The heat dissipation paths are shown by the arrows P in FIG. 7B.

In this embodiment, the third region 422 is separately disposed from the first bonding region 421, and the fourth region 432 is separately disposed from the second bonding region 431. Therefore, the energy of the energy beam L provided to the first bonding region 421 and the second bonding region 431 is partially transferred to the third region 422 and the fourth region 432. This design can moderate the heating rate and provide a more gradual heating profile at the bonding points (i.e., where the solder 30a and 30b are disposed), thereby avoiding overheating and damage to the electronic element 21. In addition, in the completed electronic device 1e, the first electrode 22a can be electrically connected to the circuit layer 41 through the solder 30a and the first bonding region 421 (cooperated with or without the third region 422), and the second electrode 22b can be electrically connected to the circuit layer 41 through the solder 30b and the second bonding region 431 (cooperated with or without the fourth region 432). Therefore, the driving current and the control signals can be input to the electronic unit 20 through the circuit layer 41 to drive the electronic unit 20 to operate.

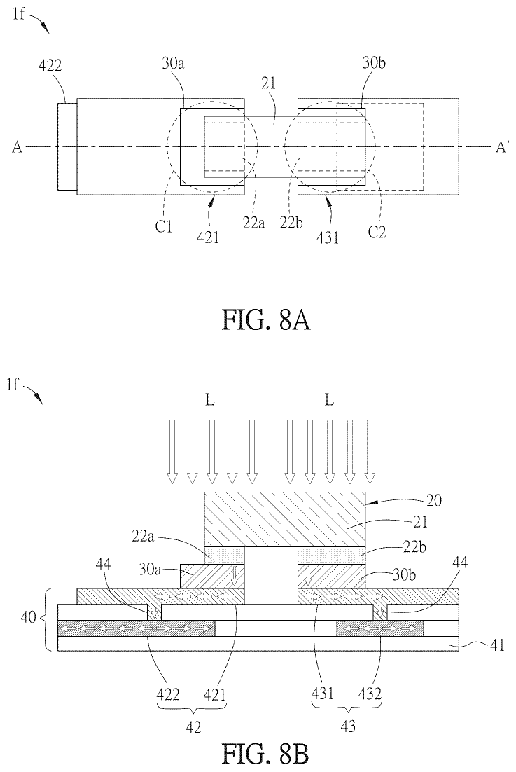

Referring to FIGS. 8A and 8B, in the electronic device 1f, the third region 422 is positioned below the first bonding region 421, and the fourth region 432 is positioned below the second bonding region 431. In this embodiment, the first bonding region 421 and the third region 422 are disposed on different metal layers, and the second bonding region 431 and the fourth region 432 are disposed on different metal layers (as shown in FIG. 8B). As shown in FIG. 8A, in the top view direction, the first bonding region 421 and the third region 422 at least partially overlap with each other, and the second bonding region 431 and the fourth region 432 at least partially overlap with each other.

To be noted, in the above embodiments, the applied energy beam L directly irradiates the first bonding region 421 and the second bonding region 431. Therefore, during reverse engineering of the electronic device, the traces formed by the direct irradiation of the energy beam L on the first bonding region 421 and the second bonding region 431 can be clearly observed, such as burn marks, scorch marks, colored patterns, local terrain changes, or the likes.

In addition, this disclosure also provides electronic devices manufactured by the above mentioned methods as shown in FIGS. 5A and 5B.

Although the disclosure has been described with reference to specific embodiments, this description is not meant to be construed in a limiting sense. Various modifications of the disclosed embodiments, as well as alternative embodiments, will be apparent to persons skilled in the art. It is, therefore, contemplated that the appended claims will cover all modifications that fall within the true scope of the disclosure.

What is claimed is:

1. A manufacturing method of an electronic device, comprising steps of:
providing a substrate, wherein the substrate comprises a bonding element, and the bonding element comprises a first region and a second region separated from each other;
providing an electronic unit, wherein the electronic unit comprises an electronic element and an electrode electrically connected to the electronic element;
transferring the electronic unit onto the substrate, wherein the electrode is stacked on the first region; and
applying an energy beam to the second region, wherein an energy of the energy beam is transmitted from the second region to the first region by heat conduction so as to bond the electrode to the first region.

2. The method of claim 1, further comprising a step of:
providing, before transferring the electronic unit onto the substrate, a solder on the first region, wherein when the electronic unit is transferred onto the substrate, the electrode overlaps the solder disposed on the first region.

3. The method of claim 2, wherein the energy of the energy beam is transmitted to the solder disposed on the first region, so that the electrode is bonded to the first region through the solder.

4. The method of claim 1, wherein the second region comprises a material with high energy absorption, while the first region comprises a material with high thermal conductivity.

5. The method of claim 1, wherein the energy beam is an infrared beam.

6. The method of claim 1, wherein the first region and the second region are disposed at one metal layer of the bonding element or different metal layers of the bonding element.

7. A manufacturing method of an electronic device, comprising steps of:
providing a substrate, wherein the substrate comprises a first bonding element and a second bonding element, the first bonding element comprises a first bonding region and a third region, and the second bonding element comprises a second bonding region and a fourth region;
providing an electronic unit, wherein the electronic unit comprises an electronic element, and the electronic unit further comprises a first electrode and a second electrode electrically connected to the electronic element;
transferring the electronic unit onto the substrate, wherein the first electrode is stacked on the first bonding region, and the second electrode is stacked on the second bonding region; and
applying an energy beam to the first bonding region and the second bonding region, wherein the first electrode is bonded to the first bonding region, and the second electrode is bonded to the second bonding region;
wherein, an area of the first electrode is smaller than an area of the second electrode, and an area of the third region is larger than an area of the fourth region.

8. The method of claim 7, further comprising a step of:
providing, before transferring the electronic unit onto the substrate, a solder on the first bonding region and the second bonding region, wherein when the electronic unit is transferred onto the substrate, the first electrode overlaps the solder disposed on the first bonding region, and the second electrode overlaps the solder disposed on the second bonding region.

9. The method of claim 8, wherein the energy of the energy beam is transmitted to the solder disposed on the first bonding region and the second bonding region, so that the first electrode and the second electrode are bonded to the first bonding region and the second bonding region, respectively, through the solder.

10. The method of claim 7, wherein the energy beam is an infrared beam.

11. The method of claim 7, wherein the first bonding region and the third region are disposed at one metal layer of the first bonding element or different metal layers of the first bonding element.

12. The method of claim 7, wherein the second bonding region and the fourth region are disposed at one metal layer of the second bonding element or different metal layers of the second bonding element.

13. An electronic device, comprising:
a substrate comprising a first bonding element and a second bonding element, wherein the first bonding element comprises a first bonding region and a third region, and the second bonding element comprises a second bonding region and a fourth region; and
an electronic unit comprising an electronic element, a first electrode and a second electrode, wherein the first electrode and a second electrode are electrically connected to the electronic element, the first electrode is stacked on the first bonding region, and the second electrode is stacked on the second bonding region;
wherein, an area of the first electrode is smaller than an area of the second electrode, and an area of the third region is larger than an area of the fourth region.

14. The electronic device of claim 13, wherein the first electrode and the second electrode are bonded to the first bonding region and the second bonding region, respectively, through at least one solder.

15. The electronic device of claim 13, wherein the first bonding region and the third region are disposed at one metal layer of the first bonding element or different metal layers of the first bonding element.

16. The electronic device of claim 13, wherein the second bonding region and the fourth region are disposed at one metal layer of the second bonding element or different metal layers of the second bonding element.

17. The electronic device of claim 13, wherein the first bonding region comprises a material with high energy absorption.

18. The electronic device of claim 17, wherein the material with high energy absorption comprises at least one of nickel, cobalt, chromium, and tungsten.

19. The electronic device of claim 13, wherein the second bonding region comprises a material with high energy absorption.

20. The electronic device of claim 19, wherein the material with high energy absorption comprises at least one of nickel, cobalt, chromium, and tungsten.
